(19) United States
(12) Patent Application Publication
(10) Pub. No.: US 2019/0378556 A1
(43) Pub. Date: Dec. 12, 2019

(54) SEMICONDUCTOR MEMORY DEVICE, POWER DECOUPLING CAPACITOR ARRAY THEREOF, AND MEMORY SYSTEM HAVING THE SAME

(71) Applicant: Samsung Electronics Co., Ltd., Suwon-si (KR)

(72) Inventors: Ju Won Lim, Hwaseong-si (KR); Ho Cheol LEE, Hwaseong-si (KR)

(21) Appl. No.: 16/189,421

(22) Filed: Nov. 13, 2018

(30) Foreign Application Priority Data
Jun. 11, 2018 (KR) 10-2018-0066600

(51) Int. Cl. G11C 11/4074; G11C 11/408; G11C 5/14; G11C 5/06

(52) U.S. Cl. CPC G11C 11/4074; G11C 5/063; G11C 5/14; G11C 11/408

(57) ABSTRACT

A semiconductor memory device, a power decoupling capacitor array thereof, and a memory system including the same are disclosed. The semiconductor memory device includes a memory cell array, a peripheral circuit, and a plurality of power decoupling capacitor arrays. The memory cell array includes a plurality of memory cells, and each of the plurality of memory cells includes a cell capacitor. Each of the plurality of power decoupling capacitor arrays includes m×n power decoupling capacitor sub arrays in an m×n matrix form. Each of the m×n power decoupling capacitor sub arrays includes a plurality of power decoupling capacitors, and each of the plurality of power decoupling capacitors has the same structure as the cell capacitor and the plurality of power decoupling capacitors are connected in parallel. A first voltage and a second voltage, which are different from each other, are applied to two of the power decoupling capacitor sub arrays arranged adjacent in a first direction and two of the power decoupling capacitor sub arrays a second direction.

### CROSS-REFERENCE TO RELATED APPLICATION

This U.S. non-provisional patent application claims priority under 35 U.S.C. § 119 to Korean Patent Application No. 10-2018-0066600, filed on Jun. 11, 2018, in the Korean Intellectual Property Office (KIPO), the content of which is hereby incorporated herein by reference in its entirety.

### BACKGROUND

### 1. Field

The inventive concept relates generally to a semiconductor memory device, a power decoupling capacitor array thereof, and a memory system including the same.

### 2. Discussion of Related Art

A semiconductor memory device may include a memory cell array and a peripheral circuit configured to input and output data to and from the memory cell array. Further, the semiconductor memory device may include a power decoupling capacitor array including a plurality of power decoupling capacitors for removing power noise that may occur between different areas of the device powered at different levels. Each of the power decoupling capacitors may be configured to be the same as a cell capacitor of each memory cell included in the memory cell array.

### SUMMARY

According to an example embodiment of the inventive concept, a semiconductor memory device, a power decoupling capacitor array thereof, and a memory system including the same may remove or reduce power noise that may occur between elements or areas of a device powered a first voltage and a second voltage, respectively, which are different from each other.

According to an example embodiment of the inventive concept, a semiconductor memory device may comprise: a memory cell array comprising a plurality of memory cells, each of the plurality of memory cells including a cell capacitor; a peripheral circuit configured to input data applied from an external source to the memory cell array or output data from the memory cell array to the external source; and a plurality of power decoupling capacitor arrays configured to reduce power noise occurring between a first voltage and a second voltage, which are different from each other, wherein each of the plurality of power decoupling capacitor arrays comprises m×n power decoupling capacitor sub arrays in an m×n matrix form, wherein each of the m×n power decoupling capacitor sub arrays comprises a plurality of power decoupling capacitors, wherein each of the plurality of power decoupling capacitors has a same structure as the cell capacitor and the plurality of power decoupling capacitors are connected in parallel, wherein the first voltage and the second voltage are applied to two of the m×n power decoupling capacitor sub arrays arranged adjacent in a first direction and two of the m×n power decoupling capacitor sub arrays arranged adjacent in a second direction, and wherein m and n are respective integer values greater than or equal to two.

According to an example embodiment of the inventive concept, a power decoupling capacitor array includes: m×n power decoupling capacitor sub arrays arranged in an m×n matrix form, wherein each of the m×n power decoupling capacitor sub arrays comprises a plurality of power decoupling capacitors, the plurality of power decoupling capacitors are connected in parallel, and a first voltage and a second voltage are applied to two power decoupling capacitor sub arrays arranged adjacent in a first direction, and two power decoupling capacitor sub arrays arranged adjacent in a second direction, wherein m and n are respective integer values greater than or equal to two, and wherein the first voltage is different than the second voltage.

According to an example embodiment of the inventive concept, a memory system includes: a memory controller; and a memory configured to input and output data in response to control signals from the memory controller, wherein the memory comprises at least one semiconductor memory device, and wherein the semiconductor memory device comprises a memory cell array comprising a plurality of memory cells, each of the plurality of memory cells comprising a cell capacitor; a peripheral circuit configured to input data from the memory controller to the memory cell array, or output data from the memory cell array to the memory controller; and a plurality of power decoupling capacitor arrays configured to reduce power noise between a first voltage and a second voltage, which are different from each other, wherein each of the plurality of power decoupling capacitor arrays comprises m×n power decoupling capacitor sub arrays arranged in an m×n matrix form, wherein each of the m×n power decoupling capacitor sub arrays comprises a plurality of power decoupling capacitors, wherein each of the plurality of power decoupling capacitors has substantially a same structure as the cell capacitor and the plurality of power decoupling capacitors are connected in parallel, wherein the first voltage and the second voltage are applied to two of the m×n power decoupling capacitor sub arrays arranged adjacent in a first direction and two of the m×n power decoupling capacitor sub arrays arranged adjacent in a second direction, and wherein m and n are respective integer values greater than or equal to two.

### BRIEF DESCRIPTION OF THE DRAWINGS

The above and other objects, features and advantages of the inventive concept will become more apparent to those of ordinary skill in the art by describing example embodiments thereof in detail with reference to the accompanying drawings, in which:

FIG. 1 is a diagram illustrating an arrangement of a semiconductor memory device according to an example embodiment of the inventive concept;

FIG. 2 is a diagram illustrating a configuration of a memory cell included in a memory cell array bank according to an example embodiment of the inventive concept;

FIG. 3 is a diagram illustrating an arrangement of a power decoupling capacitor array according to an example embodiment of the inventive concept;

FIG. 4 is an equivalent circuit of the power decoupling capacitor array shown in FIG. 3 according to an example embodiment of the inventive concept;

FIG. 5 is a cross-sectional view taken along line A-A′ of the power decoupling capacitor array of FIG. 3;

FIG. 6 is a diagram illustrating an arrangement of a power decoupling capacitor array according to an example embodiment of the inventive concept;

FIG. 7 is an equivalent circuit of the power decoupling capacitor array shown in FIG. 6 according to an example embodiment of the inventive concept;

FIG. 8 is a cross-sectional view taken along line B-B′ of the power decoupling capacitor array shown in FIG. 6;

FIG. 9 is a diagram illustrating an arrangement of a power decoupling capacitor array according to an example embodiment of the inventive concept;

FIG. 10 is an equivalent circuit of the power decoupling capacitor array shown in FIG. 9 according to an example embodiment of the inventive concept;

FIG. 11 is a diagram illustrating an arrangement of a power decoupling capacitor array according to an example embodiment of the inventive concept;

FIG. 12 is an equivalent circuit of the power decoupling capacitor array shown in FIG. 11 according to an example embodiment of the inventive concept;

FIG. 13 is a cross-sectional view taken along line C-C′ of the power decoupling capacitor array shown in FIG. 11; and

FIG. 14 is a block diagram illustrating a configuration of a memory system according to an example embodiment of the inventive concept.

### DETAILED DESCRIPTION

Hereinafter, a semiconductor memory device, a power decoupling capacitor array thereof, and a memory system including the same will be described with reference to the accompanying drawings according to embodiments of the inventive concept.

A semiconductor memory device may include a power decoupling capacitor array including a plurality of power decoupling capacitors from removing power noise that may occur as a result of different elements or areas of the device being driven by different voltage level. When the number of power decoupling sub capacitors, which are connected in parallel to increase the capacitance of the power decoupling capacitor array, increases, the high frequency characteristics of the memory device may be degraded. Some embodiments of the inventive concept stem from a realization that power decoupling capacitor sub arrays may be separately formed in an m×n matrix form, where m and n are the same integer or different integers which are 2 or more, such that a distance between the power decoupling capacitor sub arrays to which different voltages are applied is decreased. That is, because the resistance between the power decoupling capacitor sub arrays is decreased, the high frequency characteristics may be improved. Thus, the effective capacitance may be increased while the effects of power noise may be reduced.

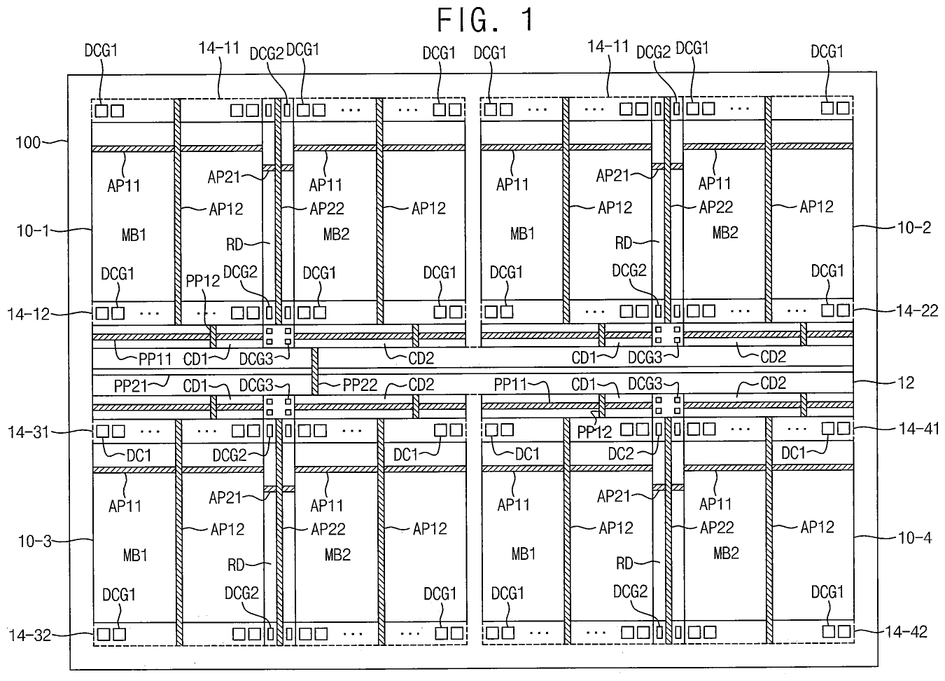

FIG. 1 is a diagram illustrating an arrangement of a semiconductor memory device according to an example embodiment of the inventive concept. A semiconductor memory device 100 may include first to fourth memory cell array regions 10-1 to 10-4, and a peripheral circuit region 12. The peripheral circuit region 12 may be disposed between the first and second memory cell array regions 10-1 and 10-2 and the third and fourth memory cell array regions 10-3 and 10-4. A memory cell array and a row decoder RD may be arranged in each of the first to fourth memory cell array regions 10-1 to 10-4. The memory cell array may include memory cell array banks MB1 and MB2. The row decoder RD may be disposed between the memory cell array banks MB1 and MB2. The memory cell array may include a plurality of memory cells (not shown), and each of the plurality of memory cells may include a cell capacitor (not shown).

Power decoupling capacitor regions 14-11 and 14-12, 14-21 and 14-22, 14-31 and 14-32, and 14-41 and 14-42 may be arranged above and below the memory cell array regions 10-1 to 10-4, respectively. Although not shown, power decoupling capacitor regions may be further arranged to each of a left side and a right side of the memory cell array regions 10-1 to 10-4. First power decoupling capacitor arrays DCG1 may be arranged in the power decoupling capacitor regions 14-11 and 14-12, 14-21 and 14-22, 14-31 and 14-32, and 14-41 and 14-42 arranged above and below each of the memory cell array banks MB1 and MB2, and second power decoupling capacitor arrays DCG2 may be arranged in the power decoupling capacitor regions 14-11 and 14-12, 14-21 and 14-22, 14-31 and 14-32, or 14-41 and 14-42 arranged above and below each of the row decoders RD.

Column decoders CD1 and CD2 and a plurality of function blocks (not shown) may be arranged in the peripheral circuit region 12. The column decoders CD1 and CD2 may be arranged below the power decoupling capacitor regions 14-12 and 14-22. Further, the column decoders CD1 and CD2 may be arranged above the power decoupling capacitor regions 14-31 and 14-41. Third power decoupling capacitor arrays DCG3 may be arranged between the column decoders CD1 and CD2. Although not shown, a plurality of power decoupling capacitor arrays may be arranged in regions, in which the plurality of function blocks are not arranged, in the peripheral circuit region 12. A peripheral circuit may comprise the column decoders CD1 and CD2 and the plurality of function blocks (not shown), and the peripheral circuit may be configured to input data applied from an external source to the memory cell array, and output data output from the memory cell array to the external source.

The first to fourth memory cell arrays 10-1 to 10-4 may include a plurality of memory cells (not shown), and each of the plurality of memory cells may include one transistor (not shown) and one cell capacitor (not shown). Each of the power decoupling capacitor arrays may include a plurality of power decoupling capacitors (not shown). The plurality of power decoupling capacitors (not shown) may be formed at the same level as the plurality of memory cells. Further, each of the plurality of power decoupling capacitors may have substantially the same capacitance as one cell capacitor of one memory cell.

A first array power line group AP11 arranged in a first direction (a horizontal direction) and a second array power line group AP12 arranged in a second direction (a vertical direction) perpendicular to the first direction and above the first array power line group AP11 may be arranged in the form of a grid (not shown) above the memory cell array banks MB1 and MB2, and the power decoupling capacitor regions 14-11 and 14-12, 14-21 and 14-22, 14-31 and 14-32, or 14-41 and 14-42 arranged above and below the memory cell array banks MB1 and MB2. A third array power line group AP21 arranged in the first direction and a fourth array power line group AP22 arranged in the second direction and above the third power line group AP21 may be arranged in the form of grid (not shown) above the row decoder RD and the power decoupling capacitor regions 14-11 and 14-12, 14-21 and 14-22, 14-31 and 14-32, or 14-41 and 14-42 arranged above and below the row decoder RD. A first peripheral power line group PP11 arranged in the first direction and a second peripheral power line group PP12 arranged in the second direction and above the first peripheral power line group PP11 may be arranged in the form of grid (not shown) above the column decoders CD1 and CD2 and the power decoupling capacitor arrays DCG3. A third peripheral power line group PP21 arranged in the first direction and a fourth peripheral power line group PP22 arranged in the second direction and above the third peripheral power line group PP21 may be arranged in the form of grid (not shown) above the plurality of function blocks (not shown) and the plurality of power decoupling capacitors (not shown).

Each of the first to fourth array power line groups AP11, AP12, AP21, and AP22, and the first to fourth peripheral power line groups PP11, PP12, PP21, and PP22 is illustrated as one line, but may include a plurality of power lines. The plurality of power lines included in the same group may transmit or carry the same voltage or transmit or carry voltages, which are different from each other.

The first array power line group AP11 and the second array power line group AP12 may be arranged on layers, which are different from each other. The third array power line group AP21 and the fourth array power line group AP22 may be arranged in layers, which are different from each other. Similarly, the first peripheral power line group PP11 and the second peripheral power line group PP12 may be arranged on layers, which are different from each other. The third peripheral power line group PP21 and the fourth peripheral power line group PP22 may be arranged on layers, which are different from each other. The first array power line group AP11, the third array power line group AP21, the first peripheral power line group PP11, and the third peripheral power line group PP21 may be arranged on the same layer, and the second array power line group AP11, the fourth array power line group AP22, the second peripheral power line group PP12, and the fourth peripheral power line group PP22 may be arranged on the same layer. Although not shown, power lines for transmitting or carrying the same voltage of the power line groups AP11 and AP12, AP21 and AP22, PP11 and PP12, or PP21 and PP22 arranged on layers, which are different from each other, may be connected to each other.

In the drawing, an example in which the power line groups are arranged on two layers, which are different from each other, is illustrated, but the power line groups may be arranged on three layers or more in accordance with various embodiments of the inventive concept.

The first power decoupling capacitor arrays DCG1 may be connected between power lines for transmitting or carrying a first voltage and a second voltage, which are different from each other, used for operation of the first to fourth memory cell arrays 10-1 to 10-4 among the first array power line group AP11 and the second array power line group AP12. The second power decoupling capacitor arrays DCG2 may be connected between power lines for transmitting or carrying a third voltage and a fourth voltage, which are different from each other, used for operation of the row decoder RD among the third array power line group AP21 and the fourth array power line group AP22. The third power decoupling capacitor arrays DCG3 may be connected between power lines for transmitting or carrying a fifth voltage and a sixth voltage, which are different from each other, used for operation of the column decoders CD1 and CD2 among the first peripheral power line group PP11 and the second peripheral power line group PP12. The power decoupling capacitor arrays (not shown) arranged in the peripheral circuit region 12 may be connected between power lines for transmitting or carrying a seventh voltage and an eighth voltage, which are different from each other, used for operation of the peripheral circuit among the third peripheral power line group PP21 and the fourth peripheral power line group PP22.

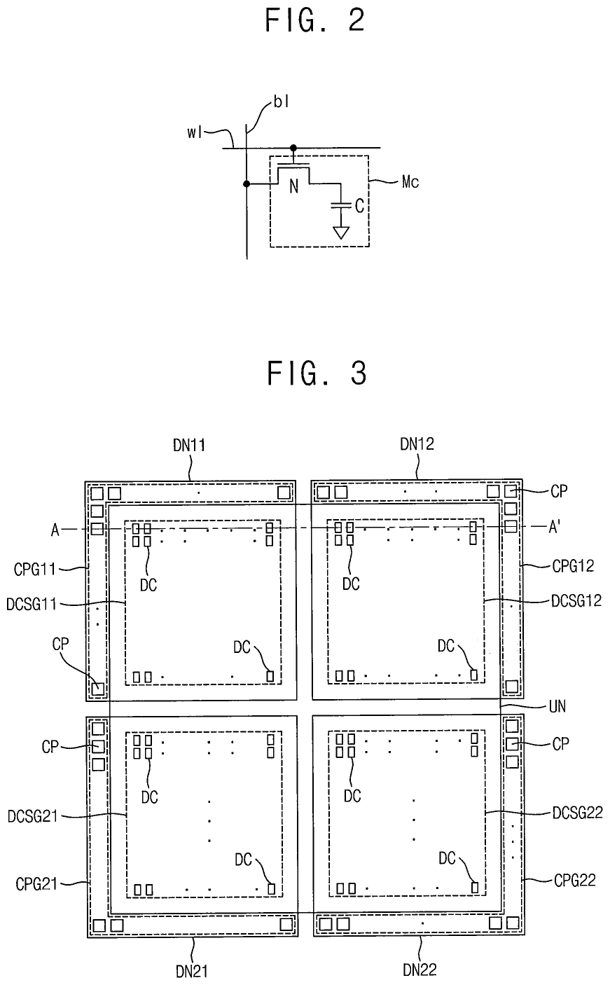

FIG. 2 is a diagram illustrating a configuration of a memory cell included in a memory cell array bank according to an example embodiment of the inventive concept. Each of the memory cell array banks MB1 and MB2 may include a plurality of memory cells connected between a plurality of word lines and a plurality of bit lines. FIG. 2 illustrates a configuration of one memory cell MC among the plurality of memory cells. The memory cell MC may include an N-type metal-oxide-semiconductor (NMOS) transistor N and a cell capacitor C connected between a word line wl and a bit line bl.

Referring to FIG. 2, the NMOS transistor N of the memory cell MC may be turned on when a high voltage VPP is applied to the word line wl, and a charge sharing operation is performed between a charge of the bit line bl and a charge stored in the cell capacitor C.

Each of the plurality of power decoupling capacitors may be formed to have substantially the same size and structure at substantially the same level as the cell capacitor C.

FIG. 3 is a diagram illustrating an arrangement of a power decoupling capacitor array according to an example embodiment of the inventive concept. The power decoupling capacitor array DCG1, DCG2, or DCG3 shown in FIG. 1 may include power decoupling capacitor sub arrays DCSG11, DCSG12, DCSG21, and DCSG22 arranged in a 2×2 matrix form, lower nodes DN11, DN12, DN21, and DN22 arranged below the power decoupling capacitor sub arrays DCSG11, DCSG12, DCSG21, and DCSG22, respectively, and an upper node UN arranged above the power decoupling capacitor sub arrays DCSG11, DCSG12, DCSG21, and DCSG22. Further, the power decoupling capacitor sub array DCSG11, DCSG12, DCSG21, or DCSG22 may include a contact plug group CPG11, CPG12, CPG21, or CPG22 arranged in a region which does not overlap the upper node UN in the lower node DN11, DN12, DN21, or DN22.

Each of the power decoupling capacitor sub arrays DCSG11, DCSG12, DCSG21, and DCSG22 may include a plurality of power decoupling capacitors DC, one end of each of the power decoupling capacitors DC may be connected to the lower node DN11, DN12, DN21, or DN22, and the other end of each of the power decoupling capacitors DC may be commonly connected to the upper node UN. The plurality of power decoupling capacitors DC may be arranged in a matrix form. Each of the plurality of power decoupling capacitors DC may be formed using the same manufacturing method as the cell capacitor C of the memory cell MC. Each of the plurality of power decoupling capacitors DC may be formed to have the same size and structure at the same level as the cell capacitor C of the memory cell MC. Accordingly, each of the plurality of power decoupling capacitors DC may have substantially the same capacitance as the cell capacitor C of the memory cell MC. The contact plug groups CPG11 and CPG12, CPG11 and CPG21, CPG12 and CPG22, and CPG21 and CPG22 may be connected to the power lines for transmitting the first voltage and the second voltage, which are different from each other, and the contact plug groups CPG11 and CPG22, and CPG12 and CPG21 may be connected to the power lines for transmitting or carrying the same first voltage or the power lines for transmitting the same second voltage.

Referring to FIG. 3, the first voltage and the second voltage, which are different from each other, may be applied to the power decoupling capacitor sub arrays DCSG11 and DCSG12, DCSG11 and DCSG21, DCSG12 and DCSG22, and DCSG21 and DCSG22 connected to the lower nodes DN11 and DN12, DN11 and DN21, DN12 and DN22, and DN21 and DN22 adjacent in the first direction and the second direction, and the same first voltage or the same second voltage may be applied to the power decoupling capacitor sub arrays DCSG11 and DCSG22, and DCSG12 and DCSG21 connected to the lower nodes DN11 and DN22, and DN12 and DN21 adjacent in the third direction (a diagonal direction).

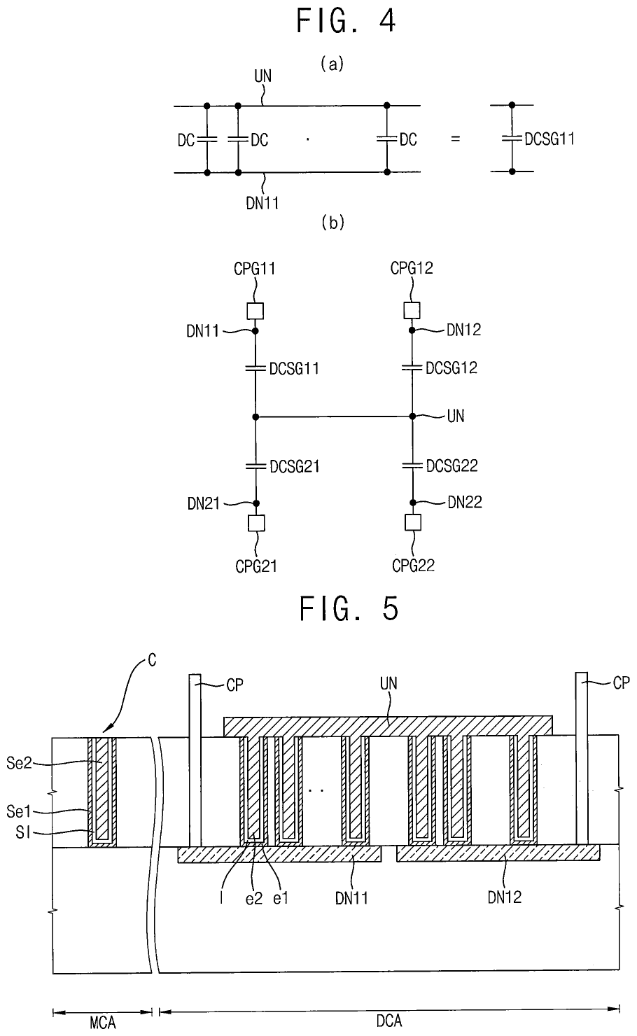

FIG. 4 is an equivalent circuit of the power decoupling capacitor array shown in FIG. 3.

Referring to FIG. 4A, the power decoupling capacitor sub array DCSG11 may comprise the plurality of power decoupling capacitors DC connected in parallel between the upper node UN and the lower node DN11.

Although not shown, each of the power decoupling capacitor sub arrays DCSG12, DCSG21, and DCSG22 may comprise the plurality of power decoupling capacitors DC connected in parallel between the upper node UN and each of the lower nodes DN12, DN21, and DN22 respectively. The power decoupling capacitor DC may have substantially the same capacitance as the cell capacitor C.

For example, when each of the power decoupling capacitor sub arrays DCSG11, DCSG12, DCSG21, and DCSG22 includes i power decoupling capacitors DC, the i power decoupling capacitors are connected in parallel, and when a capacitance of each of the power decoupling capacitors DC is Cp, a capacitance of each of the power decoupling capacitor sub arrays DCSG11, DCSG12, DCSG21, and DCSG22 may be i×Cp.

Referring to FIG. 4B, the contact plug groups CPG11, CPG12, CPG21, and CPG22 may be connected to the lower nodes DN11, DN12, DN21, and DN22, respectively. The power decoupling capacitor sub array DCSG11, DCSG12, DCSG21, or DCSG22 may be connected between the upper node UN and each of the lower nodes DN11, DN12, DN21, and DN22.

FIG. 5 is a cross-sectional view taken along line A-A′ of the power decoupling capacitor array of FIG. 3.

In FIG. 5, MCA illustrates one among the first to fourth memory cell array regions 10-1 to 10-4, and DCA illustrates one among the power decoupling capacitor regions 14-11, 14-12, 14-21, 14-22, 14-31, 14-32, 14-41, and 14-42.

Referring to FIG. 5, the cell capacitor C of the memory cell MC may include a storage electrode Se1, a cell dielectric film SI, and a plate electrode Se2. The plurality of power decoupling capacitors DC may be formed between the upper node UN and each of the lower nodes DN11 and DN12. Each of the plurality of power decoupling capacitors DC may include a first electrode e1, a dielectric film I, and a second electrode e2.

Each of the storage electrode Se1 and the first electrodes e1 may be formed to have a well structure. Each of the first electrodes e1 may be electrically connected to the lower node DN11 or DN12. Each of the cell dielectric films SI and the dielectric films I may be formed to have a well structure. The cell dielectric film SI may cover in whole or in part an inner wall of the storage electrode Se1, and each of the dielectric films I may cover in whole or in part an inner wall of the first electrode e1. The plate electrode Se2 may cover in whole or in part the dielectric film SI, and each of the second electrodes e2 may cover in whole or in part the dielectric film I. A contact plug CP may be formed in an outer side of each of the lower node DN11 and the lower node DN12.

Although not shown, the contact plug CP connected to the lower node DN11 may be connected to the power line for transmitting the first voltage, and the contact plug CP connected to the lower node DN12 may be connected to the power line for transmitting the second voltage.

As shown in FIG. 5, each of the plurality of power decoupling capacitors DC may be formed to have the same size and the same structure at the same level as the cell capacitor C of the memory cell MC. Further, each of the plurality of power decoupling capacitors DC may be formed using the same manufacturing method as the cell capacitor C of the memory cell MC.

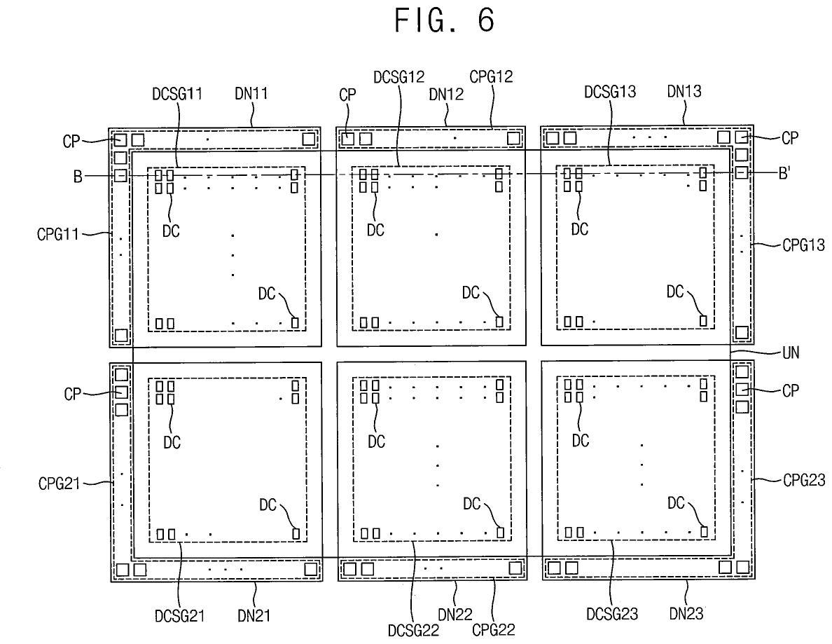

FIG. 6 is a diagram illustrating an arrangement of a power decoupling capacitor array according to an example embodiment of the inventive concept. The power decoupling capacitor array DCG1, DCG2, or DCG3 may include power decoupling capacitor sub arrays DCSG11 to DCSG13 and DCSG21 to DCSG23 arranged in a 2×3 matrix form, lower nodes DN11 to DN13 and DN21 to DN23 arranged below each of the power decoupling capacitor sub arrays DCSG11 to DCSG13 and DCSG21 to DCSG23, and an upper node UN arranged above the power decoupling capacitor sub arrays DCSG11 to DCSG13 and DCSG21 to DCSG23.

Referring to FIG. 6, each of the power decoupling capacitor sub arrays DCSG11 to DCSG13 and DCSG21 to DCSG23 may include a plurality of power decoupling capacitors DC, first ends of the plurality of power decoupling capacitors DC may be connected to the lower nodes DN11, DN12, DN13, DN21, DN22, or DN23, and second ends of the plurality of power decoupling capacitors DC may be commonly connected to the upper node UN. The plurality of power decoupling capacitors DC may be arranged in a matrix form. Each of the plurality of power decoupling capacitors DC may be formed to have the same size and the same structure at the same level as the cell capacitor C of the memory cell MC. Accordingly, each of the plurality of power decoupling capacitors DC may have substantially the same capacitance as the cell capacitor C of the memory cell MC. The plurality of contact plug groups CPG11, CPG12, CPG13, CPG21, CPG22, or CPG23 may be formed in a region, which does not overlap the upper node UN in each of the lower nodes DN11 to DN13 and DN21 to DN23.

The contact plug groups CPG11 and CPG12, CPG12 and CPG13, CPG21 and CPG22, CPG22 and CPG23, CPG11 and CPG21, CPG12 and CPG22, or CPG13 and CPG23 adjacent in the first direction or the second direction may be connected to the power lines for transmitting or carrying the first voltage and the second voltage, which are different from each other. Accordingly, the first voltage and the second voltage, which are different from each other, may be applied to the power decoupling capacitor sub arrays DCSG11 and DCSG12, DCSG12 and DCSG13, DCSG21 and DCSG22, DCSG22 and DCSG23, DCSG11 and DCSG21, DCSG12 and DCSG22, or DCSG13 and DCSG23 connected to the lower nodes DN11 and DN12, DN12 and DN13, DN21 and DN22, DN22 and DN23, DN11 and DN21, DN12 and DN22, or DN13 and DN23 adjacent in the first direction or the second direction. The contact plug groups CPG11 and CPG22, CPG12 and CPG21, CPG13 and CPG22, or CPG12 and CPG23 adjacent in the third direction may be connected to the power lines for transmitting or carrying the same first voltage or the same second voltage. Accordingly, the same first voltage or the same second voltage may be applied to the power decoupling capacitor sub arrays DCSG11 and DCSG22, DCSG12 and DCSG21, . . . , DCSG1(n−1) and DCSG2n, or DCSG1n and DCSG2(n−1) connected to the lower nodes DN11 and DN22, DN12 and DN21, DN13 and DN22, or DN12 and DN23 adjacent in the third direction.

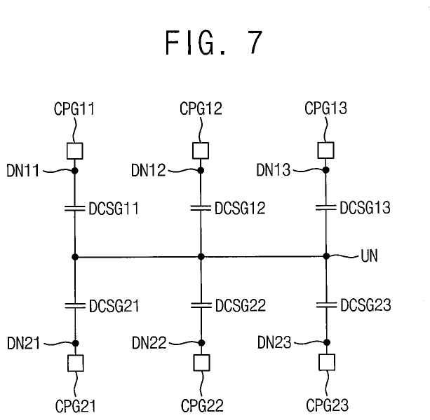

FIG. 7 is an equivalent circuit of the power decoupling capacitor array shown in FIG. 6.

Referring to FIG. 4A, each of the power decoupling capacitor sub arrays DCSG11 to DCSG13 and DCSG21 to DCSG23 may comprise the plurality of power decoupling capacitors DC connected in parallel between the upper node UN and each of the lower nodes DN11 to DN13 and DN21 to DN23. The power decoupling capacitor DC may have substantially the same capacitance as the cell capacitor C.

Referring to FIG. 7, the contact plug groups CPG11 to CPG13 and CPG21 to CPG23 may be connected to the lower nodes DN11 to DN13 and DN21 to DN23, respectively. Each of the power decoupling capacitor sub arrays DCSG11 to DCSG13 and DCSG21 to DCSG23 may be connected between the upper node UN and each of the lower nodes DN11 to DN13 and DN21 to DN23.

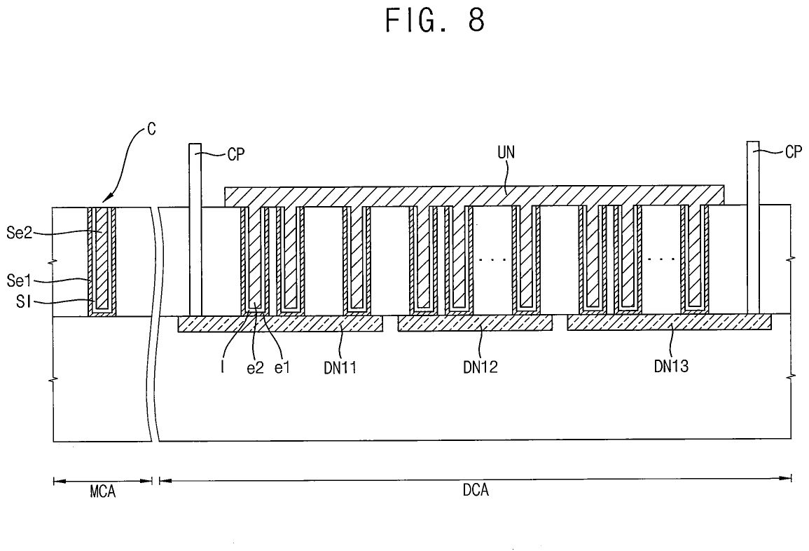

FIG. 8 is a cross-sectional view taken along line B-B′ of the power decoupling capacitor array shown in FIG. 6.

Referring to FIG. 8, since MCA and DCA have been described above with reference to FIG. 5, the description thereof will be omitted.

Referring to FIG. 8, because the cell capacitor C of the memory cell MC and each of the plurality of power decoupling capacitors DC have been described above with reference to FIG. 5, the description thereof will be omitted.

As shown in FIG. 8, each of the plurality of power decoupling capacitors DC may be formed to have the same size and the same structure at the same level as the cell capacitor C of the memory cell MC. Further, each of the plurality of power decoupling capacitors DC may be formed using the same manufacturing method as the cell capacitor C of the memory cell MC.

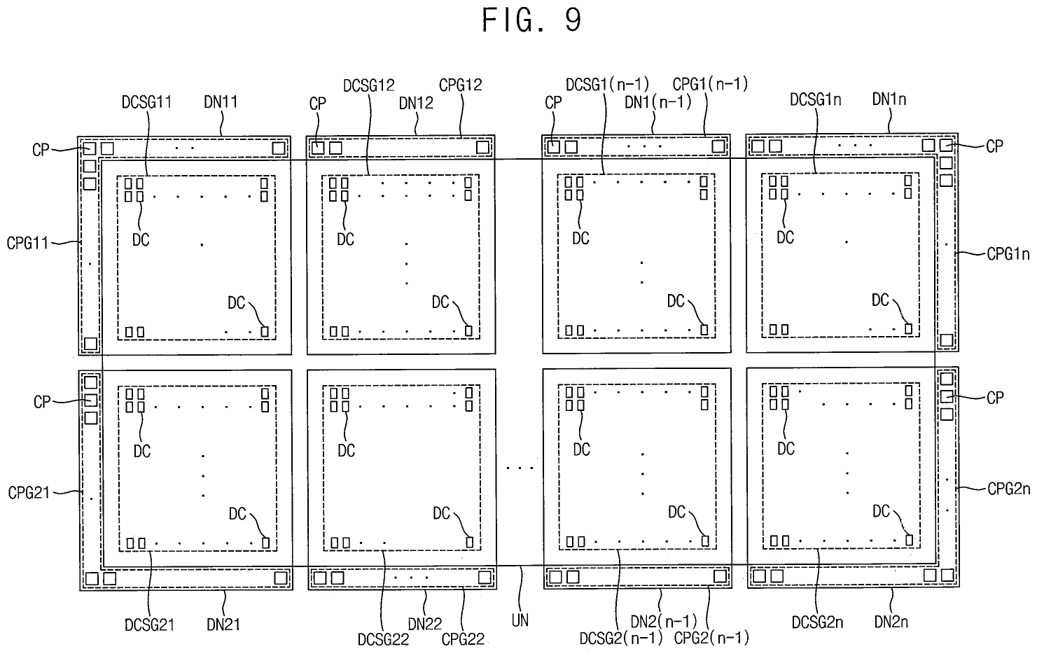

FIG. 9 is a diagram illustrating an arrangement of a power decoupling capacitor array according to an example embodiment of the inventive concept. The power decoupling capacitor array DCG1, DCG2, or DCG3 shown in FIG. 1 may include power decoupling capacitor sub arrays DCSG11 to DCSGln and DCSG21 to DCSG2n arranged in a 2×n matrix form, lower nodes DN11 to DN1n and DN21 to DN2n arranged below the power decoupling capacitor sub array DCSG11 to DCSGln and DCSG21 to DCSG2n, respectively, and an upper node UN arranged above the power decoupling capacitor sub arrays DCSG11 to DCSG1n and DCSG21 to DCSG2n. Further, the power decoupling capacitor sub array DCSG11, DCSG12, . . . , DCSG1(n−1), DCSG1n, DCSG21, DCSG22, . . . , DCSG2(n−1), or DCSG2n) may include a contact plug group CPG11, CPG12, . . . , CPG1(n−1), CPGln, CPG21, CPG22, . . . , CPG2(n−1), or CPG2n arranged in a region which does not overlap the upper node UN in the lower node DN11, DN12, . . . , DN1(n−1), DN1n, DN21, DN22, . . . , DN2(n−1), or DN2n.

Because the power decoupling capacitor sub arrays DCSG11 to DCSG1n and DCSG21 to DCSG2n shown in FIG. 9 have been described above with reference to FIG. 3 or 6, the description thereof will be omitted.

The contact plug groups CPG11 and CPG12, CPG12 and CPG13 (not shown), . . . , CPG1(n−1) and CPG1n adjacent in the first direction or the second direction may be connected to the power lines for transmitting or carrying the first voltage and the second voltage, which are different from each other. Accordingly, the first voltage and the second voltage, which are different from each other, may be applied to the power decoupling capacitor sub arrays DCSG11 and DCSG12, DCSG12 and DCSG23 (not shown), . . . , DCSG1(n−1) and DCSGln, DCSG21 and DCSG22, . . . , DCSG1(n−1) and DCSG2(n−1), or DCSGln and DCSG2n connected to the lower nodes DN11 and DN12, DN12 and DN13 (not shown), . . . , DN1(n−1) and DN1n, DN21 and DN22, DN22 and DN23 (not shown), . . . , DN2(n−1) and DN2n, DN11 and DN21, DN12 and DN22, . . . , DN1(n−1) and DN2(n−1), or DN1n and DN2n adjacent in the first direction or the second direction. The contact plug groups CPG11 and CPG22, CPG12 and CPG21, . . . , CPG1(n−1) and CPG2n, or CPGln and CPG2(n−1) adjacent in the third direction may be connected to the power lines for transmitting or carrying the same first voltage or the power lines for transmitting the same second voltage. Accordingly, the same first voltage or the same second voltage may be applied to the power decoupling capacitor sub arrays DCSG11 and DCSG22, DCSG12 and DCSG21, . . . , DCSG1(n−1) and DCSG2n, or DCSG1n and DCSG2(n−1) connected to the lower nodes DN11 and DN22, DN12 and DN21, . . . , DN1(n−1) and DN2n, or DN1n and DN2(n−1) adjacent in the third direction.

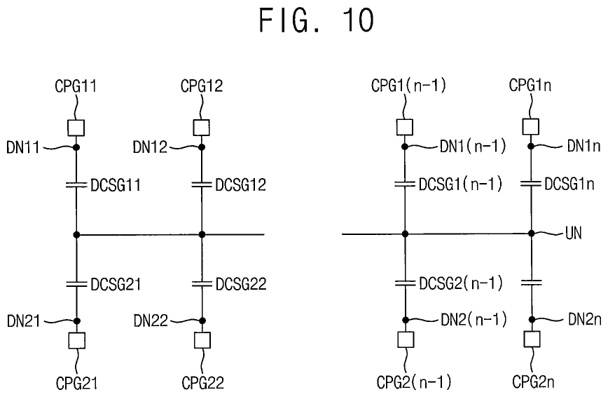

FIG. 10 is an equivalent circuit of the power decoupling capacitor array shown in FIG. 9

Referring to FIG. 10, the contact plug groups CPG11 to CPG1n and CPG21 to CPG2n may be connected to the lower nodes DN11 to DN1n and DN21 to DN2n, respectively. Each of the power decoupling capacitor sub arrays DCSG1l to DCSG1n and DCSG21 to DCSG2n may be connected between the upper node UN and each of the lower nodes DN11 to DN1n and DN21 to DN2n.

Although not shown, a cross-sectional view of the power decoupling capacitor array shown in FIG. 9 may be understood with reference to the cross-sectional view shown in FIG. 5 or 8.

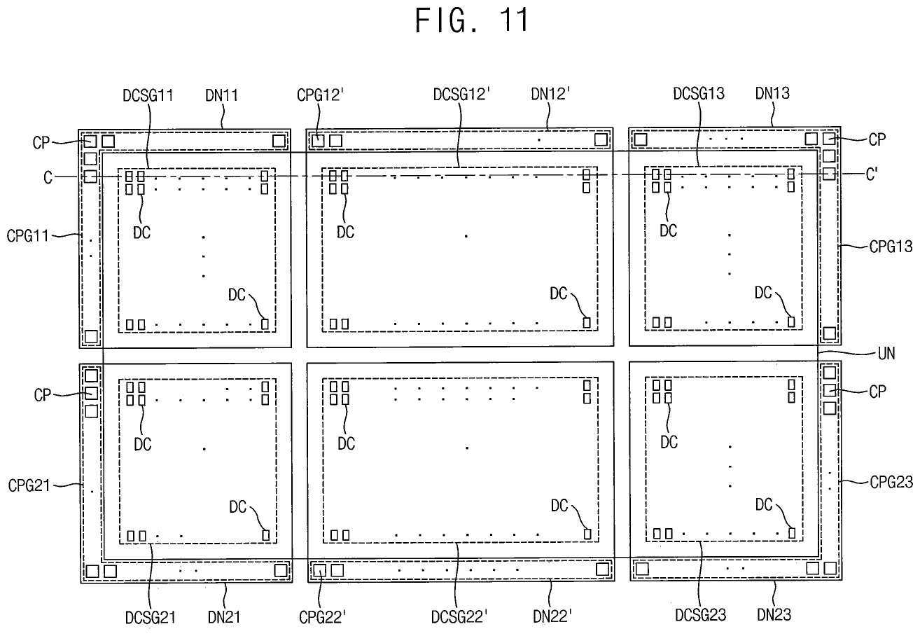

FIG. 11 is a diagram illustrating an arrangement of a power decoupling capacitor array according to an example embodiment of the inventive concept. A power decoupling capacitor array shown in FIG. 11 may have the same arrangement as the power decoupling capacitor array shown in FIG. 6 except that the power decoupling capacitor sub arrays DCSG12 and DCSG22 of the power decoupling capacitor array shown in FIG. 6 are replaced by power decoupling capacitor sub arrays DCSG12′ and DCSG22′, the lower nodes DN12 and DN22 are replaced by lower nodes DN12′ and DN22′, and the contact plug groups CPG12 and CPG22 are replaced by contact plug groups CPG12′ and CPG22′. Each of the lower nodes DN12′ and DN22′ may have a larger size than each of the lower nodes DN11, DN13, DN21, and DN23, and each of the power decoupling capacitor sub arrays DCSG12′ and DCSG22′ may have a larger size than each of the power decoupling capacitor sub arrays DCSG11, DCSG13, DCSG21, and DCSG23, and the contact plug groups CPG12′ and CPG22′ may have a larger size than the contact plug groups CPG11, CPG13, CPG21, and CPG23. That is, each of the lower nodes DN12′ and DN22′ may be larger in the first direction than each of the lower nodes DN11, DN13, DN21, and DN23. Further, the number of the plurality of power decoupling capacitors DC arranged between the upper node UN and each of the lower nodes DN12′ and DN22′ may be greater than that of the plurality of power decoupling capacitors DC arranged between the upper node UN and each of the lower nodes DN11, DN13, DN21, and DN23. Accordingly, a capacitance of the power decoupling capacitor array arranged between the upper node UN and each of the lower nodes DN12′ and DN22′ may be greater than that of the power decoupling capacitor array arranged between the upper node UN and each of the lower nodes DN11, DN13, DN21, and DN23.

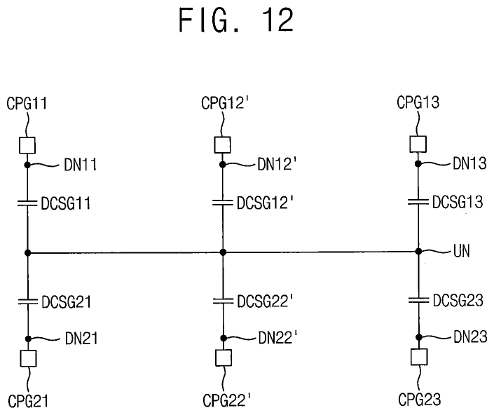

FIG. 12 is an equivalent circuit of the power decoupling capacitor array shown in FIG. 11.

Referring to FIG. 4A, a power decoupling capacitor sub array DCSG11, DCSG12′, DCSG13, DCSG21, DCSG22′, or DCSG23 may comprise a plurality of power decoupling capacitors DC connected in parallel between the upper node UN and each of the lower nodes DN11, DN12′, DN13, DN21, DN22′, and DN23. The power decoupling capacitor DC may have the same capacitance as the cell capacitor C.

Referring to FIG. 12, the contact plug groups CPG11, CPG12′, CPG13, CPG21, CPG22′, and CPG23 may be connected between the upper node UN and each of the lower nodes DN11, DN12′, DN13, DN21, DN22′, and DN23.

For example, when each of the power decoupling capacitor sub arrays DCSG11, DCSG13, DCSG21, and DCSG23 includes i power decoupling capacitors DC, each of the power decoupling capacitor sub arrays DCSG12′ and DCSG22′ includes 2i power decoupling capacitors DC, and when a capacitance of each of the power decoupling capacitors DC is Cp, a capacitance of each of the power decoupling capacitor sub arrays DCSG11, DCSG13, DCSG21, and DCSG23 may be i×Cp, and a capacitance of each of the power decoupling capacitor sub arrays DCSG12′, and DCSG22′ may be 2i×Cp.

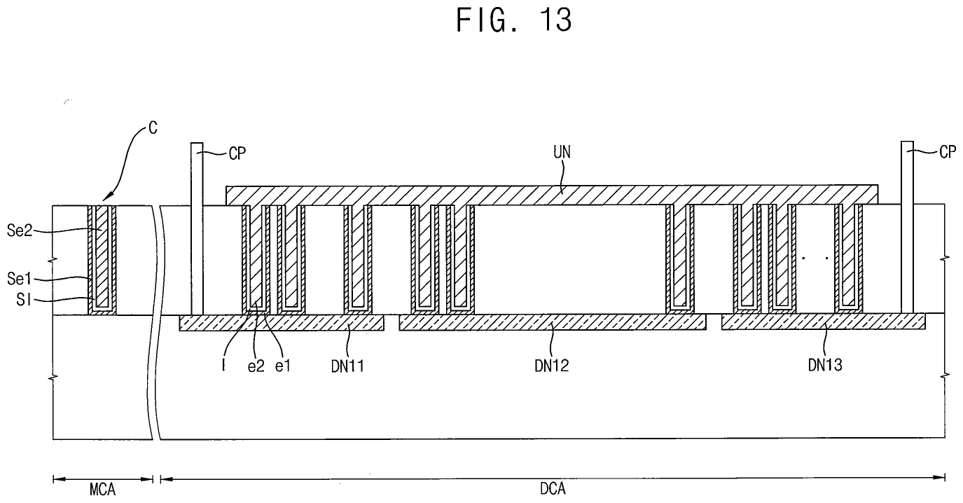

FIG. 13 is a cross-sectional view taken along line C-C′ of the power decoupling capacitor array shown in FIG. 11.

Because FIG. 13 may be understood with reference to FIG. 5 or 6 described above, the description thereof will be omitted.

Even when each of the power decoupling capacitor array shown in FIGS. 3 to 5 described above, the power decoupling capacitor array shown in FIGS. 6 to 8 described above, the power decoupling capacitor array shown in FIGS. 9 and 10, and the power decoupling capacitor array shown in FIGS. 11 to 13 described above increase the number of the power decoupling capacitors, which are connected in parallel and form a capacitor having a large size, and cause an effective capacitance to increase, because the power decoupling capacitor sub arrays are separately formed in an m×n matrix form (m and n are the same integer or different integers which are 2 or more), a distance between the power decoupling capacitor sub arrays to which different voltages are applied is decreased. That is, because the resistance between the power decoupling capacitor sub arrays is decreased and high frequency characteristics may be improved, the effective capacitance may be increased and a power noise may be efficiently decreased.

Although not shown, in FIG. 11, the power decoupling capacitor array may be configured by not including the power decoupling capacitor sub arrays DCSG21, DCSG22′, and DCSG23.

Although not shown, the lower nodes may be arranged in a layer in which the upper node is located, and the upper node may be arranged in a layer in which the lower nodes are located.

The cell capacitor C embodiments described above may be manufactured using the same or similar manufacturing methods as that of the cell capacitor C which is generally known.

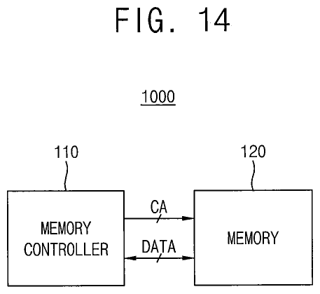

FIG. 14 is a block diagram illustrating a configuration of a memory system according to an example embodiment of the inventive concept. A memory system 1000 may include a memory controller 110, and a memory 120. The memory controller 110 may be included in the central processing unit (CPU) (not shown).

The memory 120 may be the semiconductor memory device described above with reference to FIGS. 1 to 13, or a memory module in which a plurality of semiconductor memory devices are installed.

The memory system 1000 shown in FIG. 14 may input and output data DATA in response to control of the memory controller 110. For example, the memory controller 110 may apply a command and address CA to the memory 120 and input and output data DATA to and from the memory 120. The memory 120 may store the data DATA applied from the memory controller 110 in the memory cells corresponding to an address included in the command and address CA in response to a command included in the command and address CA applied from the memory controller 110 or output data stored in the memory cells to the memory controller 110.

Even when the memory 120 shown in FIG. 14 operates at a high speed, the high frequency characteristics of the power decoupling capacitor array included in the memory 120 may improve operations thereof, and the power noise may be efficiently reduced.

According to the example embodiments of the inventive concept, the high frequency characteristics of the power decoupling capacitor array including the power decoupling capacitors may be improved, and the power noise of the semiconductor memory device may be efficiently reduced.

According to the example embodiments of the inventive concept, reliability of the semiconductor memory device and the memory system can be improved since the power noise can be efficiently reduced.

While the example embodiments of the inventive concept have been described with reference to the accompanying drawings, it should be understood by those skilled in the art that various modifications may be made without departing from the scope of the inventive concept and without changing essential features. Therefore, the above-described embodiments should be considered in a descriptive sense only and not for purposes of limitation.

What is claimed is:

1. A semiconductor memory device comprising:
a memory cell array comprising a plurality of memory cells, each of the plurality of memory cells comprising a cell capacitor;
a peripheral circuit configured to input data applied from an external source to the memory cell array or output data from the memory cell array to the external source; and
a plurality of power decoupling capacitor arrays configured to reduce power noise occurring between a first voltage and a second voltage, which are different from each other,
wherein each of the plurality of power decoupling capacitor arrays comprises m×n power decoupling capacitor sub arrays in an m×n matrix form,
wherein each of the m×n power decoupling capacitor sub arrays comprises a plurality of power decoupling capacitors,
wherein each of the plurality of power decoupling capacitors has a same structure as the cell capacitor and the m×n power decoupling capacitors are connected in parallel,
wherein the first voltage and the second voltage are applied to two of the plurality of power decoupling capacitor sub arrays arranged adjacent in a first direction and two of the m×n power decoupling capacitor sub arrays arranged adjacent in a second direction, wherein
wherein m and n are respective integer values greater than or equal to two.

2. The semiconductor memory device of claim 1, wherein each of the plurality of power decoupling capacitors is formed to have a same size at a same level as the cell capacitor.

3. The semiconductor memory device of claim 1, wherein each of the m×n power decoupling capacitor sub arrays are connected between a first node and each of m×n second nodes.

4. The semiconductor memory device of claim 3, wherein the first voltage and the second voltage are applied to the second nodes connected to the two of the m×n power decoupling capacitor sub arrays arranged adjacent in the first direction and the two of the m×n power decoupling capacitor sub arrays arranged adjacent in the second direction, and
the first voltage or the second voltage is applied to the second nodes connected to two of the m×n power decoupling capacitor sub arrays arranged adjacent in a third direction.

5. The semiconductor memory device of claim 4, wherein the first direction and the second direction are a horizontal direction and a vertical direction, respectively, and the third direction is a diagonal direction.

6. The semiconductor memory device of claim 1, wherein each of the plurality of power decoupling capacitors has substantially a same capacitance as the cell capacitor.

7. The semiconductor memory device of claim 1, wherein the m×n power decoupling capacitor sub arrays have substantially a same capacitance.

8. The semiconductor memory device of claim 1, wherein the m×n power decoupling capacitor sub arrays have substantially different capacitances.

9. The semiconductor memory device of claim 1, wherein the first voltage and the second voltage are voltages used for operation of the memory cell array or operation of the peripheral circuit.

10. The semiconductor memory device of claim 1, wherein the peripheral circuit comprises a plurality of function blocks, and
each of the plurality of power decoupling capacitor arrays is arranged in a first region surrounding the memory cell array or a second region in which the plurality of function blocks are not arranged.

11. A power decoupling capacitor array comprising:
m×n power decoupling capacitor sub arrays arranged in an m×n matrix form,
wherein each of the m×n power decoupling capacitor sub arrays comprises a plurality of power decoupling capacitors, the plurality of power decoupling capacitors are connected in parallel, and a first voltage and a second voltage are applied to two power decoupling capacitor sub arrays arranged adjacent in a first direction, and two power decoupling capacitor sub arrays arranged adjacent in a second direction,
wherein m and n are respective integer values greater than or equal to two, and
wherein the first voltage is different than the second voltage.

12. The power decoupling capacitor array of claim 11, wherein each of the m×n power decoupling capacitor sub arrays is connected between the first node and each of m×n second nodes.

13. The power decoupling capacitor array of claim 12, wherein the first voltage and the second voltage are applied to the second nodes connected to the two of the m×n power decoupling capacitor sub arrays arranged adjacent in the first direction and the two of the m×n power decoupling capacitor sub arrays arranged adjacent in the second direction, and
the first voltage or the second voltage is applied to the second nodes connected to two of the m×n power decoupling capacitor sub arrays arranged adjacent in a third direction.

14. The power decoupling capacitor array of claim 13, wherein the first direction and the second direction are a horizontal direction and a vertical direction, respectively, and the third direction is a diagonal direction.

15. The power decoupling capacitor array of claim 11, wherein the m×n power decoupling capacitor sub arrays have substantially a same capacitance or different capacitances.

16. A memory system comprising:
a memory controller; and
a memory configured to input and output data in response to control signals from the memory controller,
wherein the memory comprises at least one semiconductor memory device,
wherein the at least one semiconductor memory device comprises
a memory cell array comprising a plurality of memory cells, each of the plurality of memory cells comprising a cell capacitor,
a peripheral circuit configured to input data from the memory controller to the memory cell array, or output data from the memory cell array to the memory controller, and
a plurality of power decoupling capacitor arrays configured to reduce power noise between a first voltage and a second voltage, which are different from each other,
wherein each of the plurality of power decoupling capacitor arrays comprises m×n power decoupling capacitor sub arrays arranged in an m×n matrix form,
wherein each of the m×n power decoupling capacitor sub arrays comprises a plurality of power decoupling capacitors,
wherein each of the plurality of power decoupling capacitors has substantially a same structure as the cell capacitor and the plurality of power decoupling capacitors are connected in parallel,
wherein the first voltage and the second voltage are applied to two of the m×n power decoupling capacitor sub arrays arranged adjacent in a first direction, and two of the m×n power decoupling capacitor sub arrays arranged adjacent in a second direction, and
wherein m and n are respective integer values greater than or equal to two.

17. The memory system of claim 16, wherein each of the plurality of power decoupling capacitors is formed to have a same size at a same level as the cell capacitor.

18. The memory system of claim 16, wherein each of the m×n power decoupling capacitor sub arrays is connected between a first node and each of m×n second nodes.

19. The memory system of claim 18, wherein the first voltage and the second voltage are applied to the second nodes connected to the two of the m×n power decoupling capacitor sub arrays arranged adjacent in the first direction and the two of the m×n power decoupling capacitor sub arrays arranged adjacent in the second direction, and
the first voltage or the second voltage is applied to the second nodes connected to two power decoupling capacitor sub arrays arranged adjacent in a third direction.

20. The memory system of claim 16, wherein the m×n power decoupling capacitor sub arrays have substantially a same capacitance or different capacitances.
